(19) United States
(12) Patent Application Publication
(10) Pub. No.: US 2026/0157013 A1
(43) Pub. Date: Jun. 4, 2026

(54) WIRING SUBSTRATE AND LIGHT-EMITTING SUBSTRATE

(71) Applicants: BOE Technology Group Co., Ltd., Beijing (CN); Hefei BOE Ruisheng Technology Co., Ltd., Hefei, Anhui (CN)

(72) Inventors: Jiawei XU, Beijing (CN); Zouming XU, Beijing (CN); Xiaoxiang ZHANG, Beijing (CN); Bing WANG, Beijing (CN); Youlu LI, Beijing (CN)

(21) Appl. No.: 18/685,855

(22) PCT Filed: Feb. 27, 2023
(86) PCT No.: PCT/CN2023/078502

§ 371 Date: Feb. 22, 2024

(51) Int. Cl. H10H 29/85

(52) U.S. Cl. CPC H10H 29/857

(57) ABSTRACT

Provided is a wiring substrate. The wiring substrate includes a base substrate, a plurality of signal lines, a first protective layer, and a plurality of additional conductive portions. The base substrate includes a first region and a fan-out region. Each of the signal lines includes a first portion disposed in the first region and a second portion disposed in the fan-out region. The first protective layer includes a plurality of openings including at least one of a first opening disposed in the fan-out region and a second opening disposed in the first region. The plurality of additional conductive portions include at least one of a first additional conductive portion and a second additional conductive portion. The first additional conductive portion is electrically coupled to the signal line at the first opening, and the second additional conductive portion is electrically coupled to the signal line at the second opening.

### CROSS-REFERENCE TO RELATED APPLICATION

The present disclosure is a U.S. national stage of international application No. PCT/CN 2023/078502, filed on Feb. 27, 2023, the content of which is herein incorporated by reference in its entirety.

### TECHNICAL FIELD

The present disclosure relates to the field of display technologies, and in particular, relates to a wiring substrate and a light-emitting substrate.

### BACKGROUND

Micro light-emitting diodes are becoming widely used in the display field due to their advantages of smaller size, ultra-high brightness, long life, and the like.

### SUMMARY

According to some embodiments of the present disclosure, a wiring substrate is provided. The wiring substrate includes:
a base substrate, including: a first region and a fan-out region disposed on a side of the first region in a first direction;
a plurality of signal lines disposed on a side of the base substrate, wherein the plurality of signal lines are arranged along a second direction and extend from the first region to the fan-out region, the first direction being intersected with the second direction, and each of the plurality of signal lines includes a first portion disposed in the first region and a second portion disposed in the fan-out region;
a first protective layer disposed on a side, facing away from the base substrate, of the signal lines, wherein the first protective layer includes a plurality of openings, an orthographic projection of the openings on the base substrate being overlapped with an orthographic projection of the signal lines on the base substrate; and
a plurality of additional conductive portions disposed on the side, facing away from the base substrate, of the signal lines, wherein an orthographic projection of the additional conductive portions on the base substrate is overlapped with the orthographic projection of the openings on the base substrate, and the orthographic projection of the additional conductive portions on the base substrate is overlapped with the orthographic projection of the signal lines on the base substrate; wherein
the plurality of openings include at least one of a first opening and a second opening, the first opening being disposed in the fan-out region and the second opening being disposed in the first region; and the plurality of additional conductive portions include at least one of a first additional conductive portion and a second additional conductive portion, the first additional conductive portion being electrically connected to the signal line at the first opening and the second additional conductive portion being electrically connected to the signal line at the second opening.

In some embodiments, the plurality of signal lines include common voltage signal lines and constant voltage signal lines; wherein
at least a portion of the common voltage signal lines corresponds to at least one of the first opening and the second opening; and
at least a portion of the constant voltage signal lines corresponds to at least one of the first opening and the second opening.

In some embodiments, the first region includes a pad region, and a first bezel region and a second bezel region that are disposed in the second direction on each side of the pad region; and
the wiring substrate includes a plurality of the common voltage signal lines and a plurality of the constant voltage signal lines; wherein the first bezel region includes one of the plurality of the common voltage signal lines, and the rest of the plurality of the common voltage signal lines run through the pad region; the second bezel region includes one of the plurality of the constant voltage signal lines, and the rest of the plurality of the constant voltage signal lines run through the pad region;
the common voltage signal line in the first bezel region corresponds to at least one of the second openings;
the second additional conductive portion is electrically connected to the corresponding common voltage signal line in the first bezel region via the second opening; and a line width of the common voltage signal line in the first bezel region is less than a line width of the common voltage signal line in at least a portion of the pad region.

In some embodiments, the first region includes a pad region, and a first bezel region and a second bezel region that are disposed in the second direction on each side of the pad region; and
the wiring substrate includes a plurality of the common voltage signal lines and a plurality of the constant voltage signal lines; wherein the first bezel region includes one of the plurality of the common voltage signal lines, and the rest of the plurality of the common voltage signal lines run through the pad region; the second bezel region includes one of the plurality of the constant voltage signal lines, and the rest of the plurality of the constant voltage signal lines run through the pad region;
the constant voltage signal line in the second bezel region corresponds to at least one of the second openings;
the second additional conductive portion is electrically connected to the corresponding constant voltage signal line in the second bezel region via the second opening; and a line width of the constant voltage signal line in the second bezel region is less than a line width of the constant voltage signal line in at least a portion of the pad region.

In some embodiments, at least a portion of the plurality of the common voltage signal lines and/or the plurality of the constant voltage signal lines belong to first-type signal lines; wherein in each of the first-type signal lines, a line width of at least a partial region of the second portion is less than a line width of the first portion; and
at least a portion of the first-type signal lines is electrically connected to the corresponding first additional conductive portion via the first opening.

In some embodiments, the second portion of at least a portion of a plurality of the first-type signal lines includes: a first sub-portion extending along the first direction and electrically connected to the first portion, and a second sub-portion extending along the second direction and electrically connected to the first sub-portion;
wherein on a same one of the first-type signal lines, a line width of at least a partial region of the second sub-portion is less than the line width of the first portion, and the second sub-portion is electrically connected to the corresponding first additional conductive portion via the first opening.

In some embodiments, the second portion of a portion of the plurality of signal lines includes a first sub-portion extending along the first direction;
wherein the first sub-portion is electrically connected to the corresponding first additional conductive portion via the first opening.

In some embodiments, the orthographic projection of the opening on the base substrate is within the orthographic projection of the signal line on the base substrate, and in the second direction, a first spacing is defined between an edge of the opening and an edge of the signal line adjacent to the opening.

In some embodiments, the first spacing is greater than or equal to 5 micrometers.

In some embodiments, in a direction perpendicular to the base substrate, a thickness of the first additional conductive portion is greater than a depth of the first opening, and a thickness of the second additional conductive portion is greater than a depth of the second opening.

In some embodiments, the orthographic projection of the opening on the base substrate is within the orthographic projection of the additional conductive portion on the base substrate, and the orthographic projection of the additional conductive portion on the base substrate covers an orthographic projection of an edge of the first protective layer at the opening on the base substrate.

In some embodiments, the orthographic projection of the additional conductive portion on the base substrate is within the orthographic projection of the signal line corresponding to the additional conductive portion on the base substrate.

In some embodiments, the additional conductive portion includes a first sub-layer and a second sub-layer that are successively stacked on the side, facing away from the base substrate, of the signal lines.

In some embodiments, the signal line is made of copper, the first sub-layer is made of nickel, and the second sub-layer is made of gold.

In some embodiments, a thickness of the first sub-layer ranges from 4 microns to 5 microns, and a thickness of the second sub-layer ranges from 0.01 microns to 1 micron.

In some embodiments, the wiring substrate further includes: a plurality of pads disposed in the first region and a first conductive portion disposed on a side, facing away from the base substrate, of the pads; wherein
the first conductive portion and the additional conductive portion are made of a same material.

In some embodiments, the first conductive portion and the additional conductive portion are prepared by a same process.

In some embodiments, the plurality of pads are disposed in a pad region, and the first conductive portions are in one-to-one correspondence to the pads; and
an orthographic projection of the first conductive portion on the base substrate is overlapped with an orthographic projection of the corresponding pad on the base substrate.

In some embodiments, the wiring substrate further includes: a second protective layer, disposed on a side, facing away from the signal lines, of the additional conductive portion and covering the additional conductive portion.

In some embodiments, an orthographic projection of the first opening on the base substrate is within an orthographic projection of the second protective layer on the base substrate, and an orthographic projection of the second opening on the base substrate is within the orthographic projection of the second protective layer on the base substrate.

In some embodiments, the first protective layer is made of at least one of silicon nitride, silicon oxide, silicon nitride oxide, or amorphous silicon, and the second protective layer is made of white ink.

In some embodiments, the wiring substrate further includes: a plurality of signal input terminals; wherein
the plurality of signal input terminals disposed in the fan-out region on a same side of the base substrate as the signal lines, the plurality of signal input terminals are arranged along the second direction, and the plurality of signal input terminals are electrically connected to the signal lines; and
a portion of the first protective layer is disposed between the first opening and the signal input terminal.

In some embodiments, in the first direction, a minimum distance between the first opening and the signal input terminal ranges from 0.3 micrometers to 1 micrometer.

In some embodiments, the wiring substrate further includes a second conductive portion disposed on a side, facing away from the base substrate, of the signal input terminals, wherein the second conductive portions are in one-to-one correspondence to the signal input terminals; wherein the first protective layer includes a plurality of exposed regions, wherein an orthographic projection of the exposed regions on the base substrate is within an orthographic projection of the signal input terminals on the base substrate, and the second conductive portion covers the signal input terminal in the exposed region; and
the second conductive portion and the additional conductive portion are made of a same material.

In some embodiments, the second conductive portion and the additional conductive portion are prepared by a same process.

In some embodiments, the plurality of pads are organized into a plurality of pad groups, wherein the plurality of pad groups are disposed in the pad region on a same side of the base substrate as the signal lines, and the plurality of pad groups include a plurality of pad group columns arranged along the second direction and extending along the first direction;
each of the plurality of pad group columns corresponds to one of the constant voltage signal lines and one of the common voltage signal lines, and one of the constant voltage signal lines and one of the common voltage signal lines corresponding to each of the plurality of pad group columns are respectively disposed on two sides of the pad group column in the second direction;
each of the plurality of pad groups includes a first pad group and a second pad group;
the first pad group includes a plurality of first pads, and the constant voltage signal line is electrically connected to one of the plurality of first pads; and
the second pad group includes a ground pad, an output pad, an address pad, and a power pad; wherein the output pad and the ground pad are arranged as a first row of pad rows along the second direction, the address pad and the power pad are arranged as a second row of pad rows along the second direction, and the ground pad is electrically connected to the common voltage signal line.

According to some embodiments of the present disclosure, a light-emitting substrate is provided. The light-emitting substrate includes a wiring substrate as described above, and a plurality of light-emitting elements disposed on a side of the wiring substrate; wherein the light-emitting elements are electrically connected to the wiring substrate by pads.

In some embodiments, a first conductive portion is disposed between the pads and the light-emitting elements.

In some embodiments, the light-emitting elements are mini light-emitting diodes or micro light-emitting diodes.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of a wiring substrate according to some embodiments of the present disclosure;

FIG. 2 is an enlarged schematic view of a region B of FIG. 1 according to some embodiments of the present disclosure;

FIG. 3 is an enlarged schematic diagram of a region C of FIG. 1 according to some embodiments of the present disclosure;

FIG. 4 is an enlarged schematic view of a region D of FIG. 1 according to some embodiments of the present disclosure;

FIG. 5 is a schematic structural diagram of a cross section along a line EE′ in FIG. 2 according to some embodiments of the present disclosure;

FIG. 6 is a schematic structural diagram of a cross section along a line FF′ in FIG. 3 according to some embodiments of the present disclosure;

FIG. 7 is a schematic structural diagram of a cross section along a line II′ in FIG. 4 according to some embodiments of the present disclosure;

FIG. 8 is a schematic structural diagram of a cross section along a line JJ′ in FIG. 2 according to some embodiments of the present disclosure; and

FIG. 9 is a schematic structural diagram of a cross section along a line HH′ in FIG. 4 according to some embodiments of the present disclosure.

### DETAILED DESCRIPTION

The present disclosure is described in further detail with reference to the accompanying drawings, to clearly present the objects, technical solutions, and advantages of the present disclosure. It should be noted that the dimensions and shapes of the figures in the accompanying drawings do not reflect true proportions and are intended to schematically illustrate the present disclosure only. Obviously, the described embodiments are a portion of the embodiments of the present disclosure and not all of the embodiments. The embodiments and the features in the embodiments of the present disclosure may be combined with each other without conflict. Based on the described embodiments of the present disclosure, all other embodiments obtained by those skilled in the art without the need for creative labor fall within the scope of protection of the present disclosure.

Unless otherwise defined, technical or scientific terms used in the embodiments of the present disclosure shall have ordinary meanings understandable by persons of ordinary skill in the art to which the disclosure belongs. The terms “first,” “second,” and the like used in the embodiments of the present disclosure are not intended to indicate any order, quantity, or importance, but are merely used to distinguish the different components. The terms “comprise,” “include,” and derivatives or variations thereof are used to indicate that the element or object preceding the terms covers the element or object following the terms and its equivalents, and shall not be understood as excluding other elements or objects. The terms “connect,” “contact,” and the like are not intended to be limited to physical or mechanical connections, but may include electrical connections, either direct or indirect connection.

It should be noted that the dimensions and shapes of the figures in the accompanying drawings do not reflect true proportions and are intended only to schematically illustrate the present disclosure. The same or similar referring numerals indicate the same or similar elements or elements having the same or similar function.

In some practices, a wiring substrate of a micro light-emitting diode includes a plurality of constant voltage signal lines and a plurality of common voltage signal lines. The leftmost constant voltage signal line needs to be provided in a left bezel region, and the rightmost common voltage signal line needs to be provided in a right bezel region, and thus a width of the bezel region affects a line width of the constant voltage signal line and a line width of the common voltage signal line. For the narrow bezel product, the line width of the constant voltage signal line and the line width of the common voltage signal line need to be greatly compressed, and to ensure the electrical performance of the constant voltage signal line and the common voltage signal line, the constant voltage signal line and the common voltage signal line need to be thickened, which increases the cost of materials. Moreover, the wiring substrate has a fan-out region, and the fan-out region includes a plurality of signal input terminals. The plurality of constant voltage signal lines, the plurality of common voltage signal lines, and other types of signal lines of the wiring substrate need to be extended into the fan-out region and electrically connected to the signal input terminals. However, the space in the fan-out region is small, and thus at least some of the constant voltage signal lines and the common voltage signal lines are narrowed in the fan-out region, and the resistance of the narrowed portion is large. In this case, due to the large current in the fan-out region, the region where the line width is narrowed heats up severely.

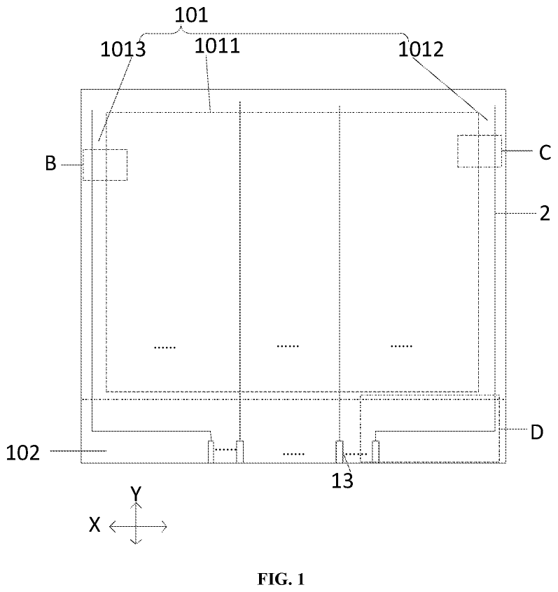

Some embodiments of the present disclosure provide a wiring substrate. As shown in FIG. 1 to FIG. 4, the wiring substrate includes:
a base substrate 1, including a first region 101 and a fan-out region 102 disposed in a first direction Y on a side of the first region 101;
a plurality of signal lines 2 disposed on a side of the base substrate 1, wherein the plurality of signal lines 2 are arranged along a second direction X and extend from the first region 101 to the fan-out region 102, the first direction Y being intersected with the second direction X, and each of the plurality of signal lines 2 includes a first portion 201 disposed in the first region 101 and a second portion 202 disposed in the fan-out region 102;
a first protective layer 3 disposed on a side, facing away from the base substrate 1, of the signal lines 2, wherein the first protective layer 3 includes a plurality of openings 301, an orthographic projection of the openings 301 on the base substrate 1 being overlapped with an orthographic projection of the signal lines 2 on the base substrate 1; and
a plurality of additional conductive portions 4 disposed on the side, facing away from the base substrate 1, of the signal lines 2, wherein an orthographic projection of the additional conductive portions 4 on the base substrate 1 is overlapped with the orthographic projection of the openings 301 on the base substrate 1, and the orthographic projection of the additional conductive portions 4 on the base substrate 1 is overlapped with the orthographic projection of the signal lines 2 on the base substrate 1.

The plurality of openings 301 include at least one of a first opening 3011 and a second opening 3012. The first opening 3011 is disposed in the fan-out region 102, and the second opening 3012 is disposed in the first region 101. The plurality of additional conductive portions 4 include at least one of a first additional conductive portion 401 and a second additional conductive portion 402. The first additional conductive portion 401 is electrically connected to the signal line 2 at the first opening 3011, and the second additional conductive portion 402 is electrically connected to the signal line 2 at the second opening 3012.

In the wiring substrate according to some embodiments of the present disclosure, the first protective layer includes openings that are overlapped with the signal lines, and the wiring substrate further includes additional conductive portions. The regions of the signal lines exposed by the openings are electrically connected to the additional conductive portions by contact, equivalent to the additional conductive portions being connected in parallel with the signal lines, and the additional conductive portions and the signal lines together serve as wirings for transmitting signals. Compared to the case where only the signal lines are provided, the resistance of the wiring for transmitting signals is reduced, and thus the impedance is reduced. In the case where the first protective layer includes the first opening, i.e., at least a portion of the signal lines disposed in the fan-out region is electrically connected to the first additional conductive portion at the first opening, the resistance of the signal line in the fan-out region is lowered. Even if a width of the signal line is reduced after the signal line is extended into the fan-out region, the heating of the signal line in the fan-out region is reduced or even avoided. In the case where the first protective layer includes the second opening, i.e., at least a portion of the signal lines disposed in the first region is covered by the second conductive portion at the second opening, the resistance of the signal line in the first region is reduced, such that a line width of the signal line in the first region is reduced while satisfying the need for the impedance of the signal line, which facilitates the achievement of a narrow bezel.

It should be noted that the plurality of openings including at least one of the first opening and the second opening indicates that the plurality of openings include a plurality of first openings and/or a plurality of second openings. That is, the plurality of openings include a plurality of first openings without including the second openings, the plurality of openings include a plurality of second openings without including the first openings, or the plurality of openings include a plurality of first openings and a plurality of second openings. The plurality of first openings and/or the plurality of second openings included in the plurality of openings correspond to at least a portion of the signal lines. In specific embodiments, in a direction perpendicular to the base substrate, a thickness of the opening is greater than or equal to 5 micrometers and less than or equal to 20 micrometers.

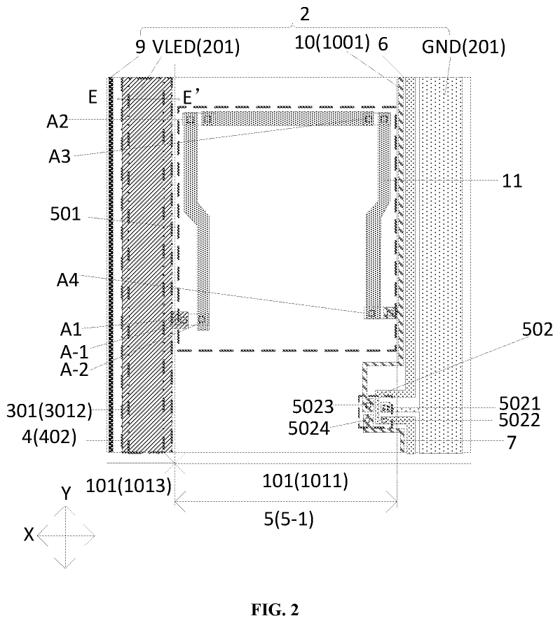

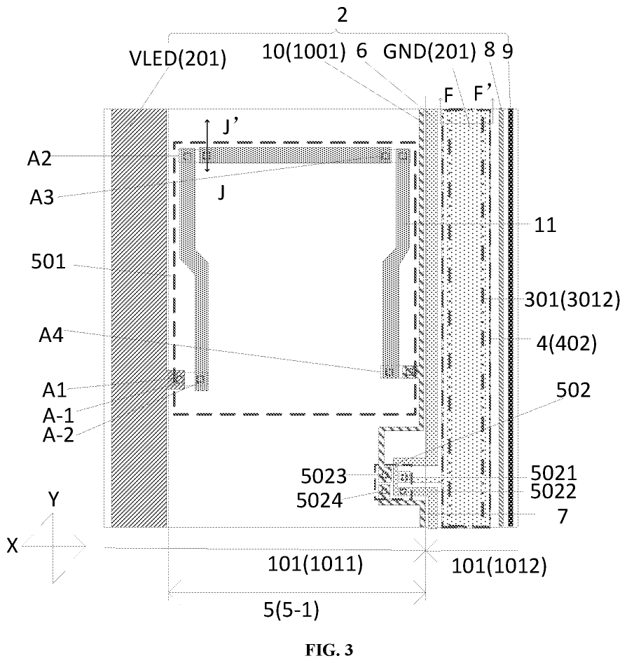

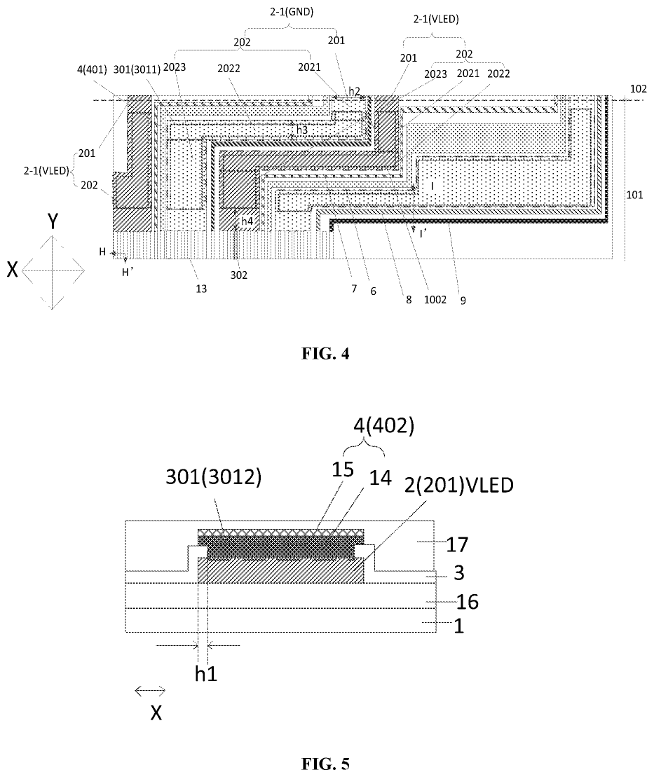

It should be noted that FIG. 2 is an enlarged schematic view of a region B of FIG. 1 according to some embodiments of the present disclosure, FIG. 3 is an enlarged schematic diagram of a region C of FIG. 1 according to some embodiments of the present disclosure, and FIG. 4 is an enlarged schematic view of a region D of FIG. 1 according to some embodiments of the present disclosure. In FIG. 2 to FIG. 4, the arrangement positions of the openings and the additional conductive portions are only illustrated by dotted lines. In FIG. 1 to FIG. 4, the first direction Y is perpendicular to the second direction X.

It should be noted that the first portion and the second portion are disposed in the same layer. In some embodiments, the first portion and the second portion are disposed in different layers.

In some embodiments, as shown in FIG. 2 to FIG. 4, an orthographic projection of the first opening 3011 on the base substrate 1 is within the orthographic projection of the signal line 2 on the base substrate 1, an orthographic projection of the second opening 3012 on the base substrate 1 is within the orthographic projection of the signal line 2 on the base substrate 1; the orthographic projection of the first opening 3011 on the base substrate 1 is within an orthographic projection of the first additional conductive portion 401 on the base substrate 1, and the orthographic projection of the second opening 3012 on the base substrate 1 is within an orthographic projection of the second additional conductive portion 402 on the base substrate 1. That is, the openings expose only the signal lines and not the rest of the wiring substrate. At the first opening, the first additional conductive portion completely covers a portion, exposed by the first opening, of the signal line, and at the second opening, the second additional conductive portion completely covers a portion, exposed by the second opening, of the signal line.

In some embodiments, as shown in FIG. 1 to FIG. 3, the first region 101 includes a pad region 1011, and a first bezel region 1012 and a second bezel region 1013 that are disposed on either side of the pad region 1011 in the second direction X, respectively.

In some embodiments, as shown in FIG. 2 and FIG. 3, the plurality of signal lines 2 include a plurality of common voltage signal lines GND and a plurality of constant voltage signal lines VLED.

The first bezel region 1012 includes one of the plurality of common voltage signal lines GND, and the remaining common voltage signal lines GND run through the pad region 1011. The second bezel region 1013 includes one of the plurality of constant voltage signal lines VLED, and the remaining constant voltage signal lines VLED run through the pad region 1011.

In some embodiments, in the pad region, the wiring substrate further includes a plurality of pads. The plurality of pads are organized into a plurality of pad groups 5 as shown in FIG. 2 and FIG. 3. The plurality of pad groups 5 are disposed in the pad region 1011 on the same side of the base substrate 1 as the signal lines 2. The plurality of pad groups 5 include a plurality of pad group columns 5-1. The plurality of pad groups 5 are arranged along the second direction X and extending along the first direction Y.

Each pad group column 5-1 of the plurality of pad group columns 5-1 corresponds to one of the constant voltage signal lines VLED and one of the common voltage signal lines GND. One constant voltage signal line VLED and one common voltage signal line GND that correspond to each pad group column 5-1 are respectively disposed in the second direction X on both sides of the pad group columns 5-1.

Each of the pad group columns 5-1 includes a plurality of first pad groups 501 and a plurality of second pad groups 502.

The first pad group 501 includes a plurality of first pads A, and the constant voltage signal line VLED is electrically connected to one of the plurality of first pads A.

The second pad group 502 includes a ground pad 5021, an output pad 5023, an address pad 5024, and a power pad 5022. The output pad and the ground pad are arranged as a first row of pad rows along the second direction X. The address pad and the power pad are arranged as a second row of pad rows along the second direction X. The ground pad is electrically connected to the common voltage signal line GND.

It should be noted that the description of FIG. 2 and FIG. 3 is given using a scenario where the first pad group 501 includes four first pads A successively connected as an example. Each pad is regarded as a whole, and the plurality of first pads A are connected in series with each other. The four first pads A are A1, A2, A3, and A4 respectively, and the constant voltage signal line VLED is electrically connected to the first pad A1. In specific embodiments, the plurality of first pads included in the first pad group are connected in other ways, such as connecting the plurality of first pads in parallel when each pad is regarded as a whole. That is, the plurality of first pads are connected in series or parallel when each pad is regarded as a whole.

It should be noted that the wiring substrate according to some embodiments of the present disclosure is applied to a light-emitting substrate, where each of the first pad groups is bound to a light-emitting element, and the constant voltage signal line is configured to provide a constant voltage signal to the first pad group. In specific embodiments, the light-emitting element is, for example, a light-emitting device. The second pad group is bound to a drive chip, such that the light-emitting element is driven to operate under the control of the drive chip. For example, one of the second pad groups corresponds to one of the first pad groups, and a corresponding drive chip controls the operation of each light-emitting element in the first pad group corresponding to the drive chip. In specific embodiments, the power pad provides working voltage and communication data for the drive chip. The communication data is configured to control the working state of the corresponding light-emitting component. A drive signal is a drive current, configured to drive the light-emitting element electrically connected to the second pad group where the output pad is located. The drive chip provides the working voltage and communication data for the next cascade of drive chip through the power pad. The output pad outputs the drive signal. The first address pad receives an address signal for gating the drive chip of the corresponding address. The drive chip also generates a relay signal and outputs the relay signal through the second address pad. The relay signal serves as the address signal of the first address pad in the next cascade of second pad group. The ground pad receives a common voltage signal transmitted by the common voltage signal line.

In specific embodiments, as shown in FIG. 2, FIG. 3, and FIG. 4, the plurality of signal lines further include a plurality of address signal lines 10, a plurality of cascade lines 7, a plurality of power signal lines 6, a feedback signal line 8, and an electrostatic shielding line 9. The feedback signal line 8 is disposed within the first bezel region 1012. The address signal lines 10, the cascade lines 7, and the power signal lines 6 include portions disposed within the pad region 1011. The address signal lines 10 include a first address signal line 1001 and a second address signal line 1002. The plurality of second pad groups 502 in one of the pad group columns 5-1 are arranged in cascade. In the same column, the address pad 5024 of the second pad group 502 of the first cascade is connected to the first address signal line 1001, and the output pad 5023 of the second pad group 502 of the k^{th} (k is a positive integer) cascade is connected to the address pad 50234 of the second pad group 502 of the (k+1)^{th} cascade by the cascade line 7, and the output pad 5023 of the second pad group 502 of the last cascade is connected to the feedback signal line 8. The second address signal line 1002 is disposed between the common voltage signal line GND and the constant voltage signal line VLED that are disposed between adjacent two of the pad group columns, and the second address signal line 1002 is connected to the first address signal line 1001 at a side, distal from the fan-out region, of the pad region. The cascade line 7 is electrically connected to one of the first pads A (A4 in FIG. 2 and FIG. 3) in the first pad group 501. Each power pad 5022 in a column of pad group columns 5-1 is electrically connected to the same power signal line 6. Each ground pad 5021 in a column of pad group columns 5-1 is electrically connected to the same common voltage signal line GND.

In specific embodiments, as shown in FIG. 2 and FIG. 3, among the various types of wirings electrically connected to the pad group column 5-1, the cascade line 7 and the power signal line 6 are disposed between the first pad group 501 and the common voltage signal line GND, the cascade line 7 is disposed in a region between the power signal line 6 and the first pad group 501, and the address signal line 10 is disposed on a side, facing away from the common voltage signal line GND adjacent thereto, of the power signal line 6.

In some embodiments, as shown in FIG. 2 and FIG. 3, the electrostatic shielding line 9 runs through the first bezel region 1012 and the second bezel region 1013. The first bezel region 1012 includes the electrostatic shielding line 9, the power signal line 6, the feedback signal line 8, and the fixed voltage signal line GND, and the second bezel region 1013 includes the electrostatic shielding line 9 and the constant voltage signal line VLED.

In some embodiments, as shown in FIG. 1, the power signal line 6 is integrally connected to the power pad 5022. The power signal line 6 is electrically connected to the power pad 5022, running through a region between the ground pad 5021 and the output pad 5023. The ground pad 5021 is electrically connected to the common voltage signal line GND.

In some embodiments, as shown in FIG. 2 and FIG. 3, the first pad A includes a first sub-pad A-1 and a second sub-pad A-2. The plurality of the first pads A in the first pad group 501 are connected in series by a first connection lead 11.

In specific embodiments, as shown in FIG. 2 and FIG. 3, the first pad group 501 includes three first connection leads 11, two longitudinal first connection leads 11 extending along the first direction Y and one transverse first connection lead 11 extending along the second direction X. The first pad A1 is electrically connected to the first pad A2 by the longitudinal first connection lead 11, the first pad A3 is electrically connected to the first pad A4 by the longitudinal first connection lead 11, and the first pad A2 is electrically connected to the first pad A3 by the transverse first connection lead 11.

It should be noted that the description of FIG. 2 and FIG. 3 is given using a scenario where the plurality of first pads are connected in series as an example. In specific embodiments, the plurality of first pads are connected in parallel.

In some embodiments, at least a portion of the common voltage signal lines correspond to at least one of the first opening and the second opening.

At least a portion of the constant voltage signal lines correspond to at least one of the first opening and the second opening.

That is, the common voltage signal line is electrically connected to the first additional conductive portion via the first opening and/or electrically connected to the second additional conductive portion via the second opening, such that the resistance of at least a portion of the common voltage signal line at a region corresponding to the first opening and/or the second opening is lowered, and thus the impedance is reduced. The constant voltage signal line is electrically connected to the first additional conductive portion via the first opening and/or electrically connected to the second additional conductive portion via the second opening, such that the resistance of at least a portion of the constant voltage signal line at a region corresponding to the first opening and/or the second opening is reduced, and thus the impedance is reduced.

In some embodiments, the common voltage signal line GND included in the first bezel region 1012 corresponds to the at least one second opening 3012, as shown in FIG. 3.

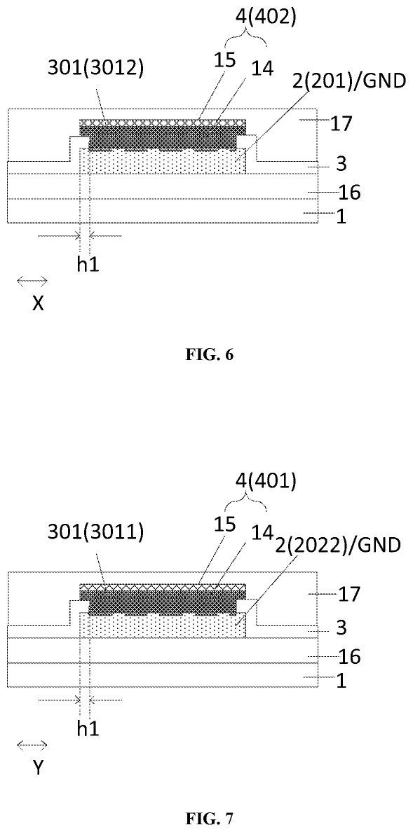

As shown in FIG. 6, the second additional conductive portion 402 is electrically connected to the corresponding common voltage signal line GND in the first bezel region 1012 via the second opening 3012.

It should be noted that FIG. 6 is a schematic structural diagram of a cross section along a line FF′ in FIG. 3.

In the wiring substrate according to some embodiments of the present disclosure, the common voltage signal line included the first bezel region corresponds to at least one second opening, and the second additional conductive portion is in contact with the common voltage signal line of the first bezel region at the second opening to realize an electrical connection, which is equivalent to the second additional conductive portion being connected in parallel with the common voltage signal line at the second opening of the first bezel region, such that the resistance of the common voltage signal line in the first bezel region is reduced, and the impedance of the common voltage signal line is reduced. Therefore, in the case of satisfying the need for the impedance of the common voltage signal line and not changing a thickness of the signal line, a line width of the common voltage signal line in the first bezel region is reduced, and thus a width of the first bezel region in the second direction is reduced, which facilitates the achievement of the narrow bezel.

In some embodiments, among the plurality of common voltage signal lines, only the common voltage signal line disposed within the first bezel region corresponds to at least one second opening, and the common voltage signal line that runs through the pad region does not correspond to the second opening. That is, only the common voltage signal line disposed within the first bezel region is connected in parallel with the second additional conductive portion, and the common voltage signal line that runs through the pad region is not connected in parallel with the second additional conductive portion. Accordingly, the resistance is reduced by the parallel connection of the common voltage signal line in the first bezel region with the second additional conductive portion, and therefore, in a case were the impedance requirement of the signal line is satisfied, the line width of the common voltage signal line in the first bezel region is defined to be less than the line width of at least a portion of the common voltage signal line in the pad region. In specific embodiments, the line widths of the common voltage signal lines running through the pad region are equal, and thus the line width of the common voltage signal line in the first bezel region is less than the line width of each of the common voltage signal lines running through the pad region.

Alternatively, in some embodiments, among the plurality of common voltage signal lines, in addition to the common voltage signal line disposed within the first bezel region corresponding to at least one second opening, the common voltage signal line that runs through the pad region also corresponds to the second opening. That is, each of the common voltage signal lines is connected in parallel with the second additional conductive portion, such that the resistance of each of the common voltage signal lines is reduced. Compared to the technical solution in the related without the second additional conductive portion, in the case where the impedance requirement of the signal line is satisfied, the line width of the common voltage signal line in the first bezel region and the line width of the common voltage signal line running through the pad region are reduced, which facilitates the achievement of the narrow bezel and is conducive to improving the wiring space of the pad group columns. In addition, more pad group columns are arranged, and thus the pixel density is increased compared to some practices. Alternatively, the number of first pads in the first pad region of the pad group column is increased by increasing the wiring space of the pad group column, such that the first pad region is bound to more light-emitting elements, and when the light-emitting elements are light-emitting devices, the luminous intensity of each first pad region is increased.

In some embodiments, as shown in FIG. 2, the constant voltage signal line VLED included in the second bezel region 1013 corresponds to at least one second opening 3012.

As shown in FIG. 5, the second additional conductive portion 402 is electrically connected to the corresponding constant voltage signal line VLED in the second bezel region 1013 via the second opening 3012.

The width of the constant voltage signal line VLED in the second bezel region 1013 is less than the width of the constant voltage signal line VLED in at least a portion of the pad region 1011.

It should be noted that FIG. 5 is a schematic structural diagram of a cross section along a line EE′ in FIG. 2.

In the wiring substrate according to some embodiments of the present disclosure, the constant voltage signal line included in the second bezel region corresponds to at least one second opening, and the second additional conductive portion is in contact with the constant voltage signal line in the second bezel region at the second opening to realize an electrical connection, which is equivalent to the second additional conductive portion being connected in parallel with the constant voltage signal line in the second opening of the second bezel region, and thus the resistance of the constant voltage signal line in the second bezel region is reduced. Thereby, in the case where the need for the impedance of the constant voltage signal line is satisfied, the line width of the constant voltage signal line in the second bezel region is reduced, and thus the width of the second bezel region in the second direction is reduced, which is conducive to achieving the narrow bezel.

In some embodiments, among the plurality of constant voltage signal lines, only the constant voltage signal line disposed within the second bezel region corresponds to the at least one second opening, and the constant voltage signal line running through the pad region does not correspond to the second opening. That is, only the constant voltage signal line disposed within the second bezel region is connected in parallel with the second additional conductive portion, and the constant voltage signal line running through the pad region is not connected in parallel with the second additional conductive portion. Accordingly, the resistance is reduced by the parallel connection of the constant voltage signal line in the second bezel region with the second additional conductive portion, and therefore, in the case where the impedance requirement of the signal line is satisfied, the line width of the constant voltage signal line in the second bezel region is defined to be less than the line width of the constant voltage signal line in at least a portion of the pad region. In specific embodiments, the line widths of the constant voltage signal lines running through the pad region are equal, and thus the line width of the constant voltage signal line in the second bezel region is less than the line width of each of the constant voltage signal lines running through the pad region.

Alternatively, in some embodiments, among the plurality of constant voltage signal lines, in addition to the constant voltage signal line disposed within the second bezel region corresponding to at least one second opening, the constant voltage signal line running through the pad region also corresponds to the second opening. That is, each of the constant voltage signal lines is connected in parallel with the second additional conductive portion, such that the resistance of each constant voltage signal line is lowered. Compared to some practices without providing the second additional conductive portion, in the case where the impedance requirement of the signal line is satisfied, the line width of the constant voltage signal line in the second bezel region and the line width of the constant voltage signal line running through the pad region are reduced, which facilitates the achievement of the narrow bezel and the improvement of the wiring space of the pad group column. Further, compared to some practices, more pad groups are provided, and thus the pixel density is increased. Alternatively, the number of first pads in the first pad region of the pad group column is increased by increasing the wiring space of the pad group column, such that the first pad region is bound to more light-emitting elements, and when the light-emitting elements are light-emitting devices, the luminous intensity of each first pad region is increased.

In specific embodiments, in addition to the common voltage signal lines and the constant voltage signal lines, in a case where there is a need to reduce the resistance of any of the remaining various signal lines, the remaining various signal lines also correspond to the second openings and are electrically connected to the second additional conductive portion at the second openings, if the process condition permits.

In some embodiments, as shown in FIG. 1 and FIG. 4, the wiring substrate further includes a plurality of signal input terminals 13.

The plurality of signal input terminals 13 are disposed in the fan-out region 102 on the same side of the base substrate 1 as the signal lines 2. The plurality of signal input terminals 13 are arranged along the second direction X, and at least some of the signal input terminals 13 are electrically connected to the signal lines 2.

In specific embodiments, when the wiring substrate is applied to the light-emitting substrate, the light-emitting substrate further includes a drive control module for providing corresponding signals to the various types of signal lines. The signal input terminals are bound to the drive control module, such that the signals provided by the drive control module are transmitted to the corresponding signal lines through these signal input terminals.

In specific embodiments, for ease of fabrication, in the second direction, widths of the signal input terminals are defined be equal, and any adjacent two of the signal input terminals are equidistant from each other. The signal line extending to the fan-out region is electrically connected to one of the signal input terminals or the plurality of signal input terminals, depending on a line width of a region where the signal line is electrically connected to the signal input terminal. The plurality of signal input terminals also include dummy signal input terminals that are not electrically connected to the signal lines.

In some embodiments, the plurality of signal lines include a plurality of first-type signal lines. On the same first-type signal line, a line width of at least a portion region of the second portion is less than a line width of the first portion. That is, the first-type signal line is a signal line that has a region of reduced line width in the fan-out region. In the fan-out region, the signal line in the region of reduced line width is susceptible to heating issues.

In some embodiments, at least a portion of the first-type signal lines is electrically connected to a corresponding first additional conductive portion via the first opening. That is, a second portion of the at least a portion of the first-type signal lines disposed within the fan-out region is connected in parallel with the first additional conductive portion at the first opening, such that the resistance of the at least a portion of the first-type signal lines is reduced, and thus the problem that at least a portion of the first-type signal lines heat up in the fan-out region due to the reduced line width is avoided.

In some embodiments, at least a portion of the plurality of common voltage signaling lines GND and/or the plurality of constant voltage signaling lines VLED is the first-type signal line 2-1, as shown in FIG. 4.

At least a portion of the common voltage signal lines GND and/or the constant voltage signal lines VLED that belong to the first-type signal line 2-1 is electrically connected to a corresponding first additional conductive portion 401 via the first opening 3011.

It should be noted that the description of FIG. 4 is given using a scenario where at least a portion of the plurality of common voltage signal lines GND is the first-type signal line 2-1 and at least a portion of the plurality of constant voltage signal lines VLED is the first-type signal line 2-1 as an example. The region of the first opening 3011 and the region of the first additional conductive portion 401 are illustrated by dashed lines only in FIG. 4. The cross-sectional view of the first opening is shown in FIG. 7, which is a cross-sectional view along a line II′ in FIG. 4. The description of FIG. 7 is given using the common voltage signal line belonging to the first-type signal line as an example.

It should be noted that in the wiring substrate, the line widths of the address signal line, the electrostatic shielding line, and the feedback signal line are about 200 micrometers, the line width of the power signal line is about 400 micrometers, and the line widths of the common voltage signal line GND and the constant voltage signal line VLED are wider. Even though the line widths of the common voltage signal line GND and the constant voltage signal line VLED that are in the bezel region are less than the line widths of the common voltage signal line GND and the constant voltage signal line VLED that are in the pad region, the line widths of the common voltage signal line GND and the constant voltage signal line VLED in the bezel region are still large, which are about 1000 μm. Therefore, in the case where the common voltage signal line GND and the constant voltage signal line VLED extend into the fan-out region, the line widths of the two decrease in a larger ratio due to the limited space of the wiring, and thus the heating issues are more likely to occur.

In the wiring substrate according to some embodiments of the present disclosure, the common voltage signal line GND and the constant voltage signal line VLED that at least partially belong to the first-type signal lines correspond to the first opening. That is, in the fan-out region, the common voltage signal line GND and the constant voltage signal line VLED hat at least partially belong to the first-type signal line are in contact with the first additional conductive portion at the first opening to realize the parallel connection, such that the resistance of the signal line is reduced, and the issue that the common voltage signal line GND and the constant voltage signal line VLED, which are at least partially disposed within the fan-out region, heat up due to a reduction in the line width of the line, is avoided.

In some embodiments, each of the common voltage signal lines GND and each of the constant voltage signal lines VLED, belonging to the first-type signal line 2-1, are electrically connected to the corresponding first additional conductive portion 401 via the first opening 3011. Thereby, the issue that the common voltage signal line GND and the constant voltage signal line VLED that are disposed in the fan-out region heat up due to the reduction of the line width is avoided to the greatest extent.

In specific embodiments, in a case where the remaining first-type signal lines other than the common voltage signal line GND and the constant voltage signal line VLED also have the issue of heating due to the reduction of the line width, the remaining first-type signal lines also correspond to the first openings if the process condition permits. That is, the remaining first-type signal lines are also electrically connected to the first additional conductive portion via the first openings to reduce the resistance.

It should be noted that the fan-out region has a smaller width in the first direction, such that the signal lines have less wiring space in the first direction after extending into the fan-out region, which affects a line width of a portion of the signal line extending in the fan-out region along the second direction. That is, the line width of the portion of the signal line that extends in the fan-out region along the second direction is reduced.

In some embodiments, as shown in FIG. 4, the second portion 202 of at least a portion of the plurality of first-type signal lines 2 includes a first sub-portion 2021 extending along the first direction Y and electrically connected to the first portion 201, and a second sub-portion 2022 extending along the second direction X and electrically connected to the first sub-portion 2021.

A line width h3 of at least a portion of the second sub-portion 2022 is less than a line width h2 of the first portion 201.

The second sub-portion 2022 is electrically connected to a corresponding first additional conductive portion 401 via the first opening 3011.

That is, at least a portion of the first-type signal line has a reduced line width in a partial region of the second sub-portion extending along the second direction X, and the first opening corresponds to at least a region where the line width of the second sub-portion is less than the line width of the first portion, such that the first additional conductive portion is connected in parallel with the second sub-portion at least in that region, and thus the resistance in that region is reduced and the heating issue in that region is avoided.

In specific embodiments, for the first opening corresponding to the second sub-portion, an orthographic projection of the first opening on the base substrate covers at least an orthographic projection of the region, where the line width of the second sub-portion is less than the line width of the first portion, on the base substrate, such that the resistance of the region is reduced.

In some embodiments, as shown in FIG. 4, in a case where the second portion 202 includes the second sub-portion 2022, the second portion 202 further includes a third sub-portion 2023. Two ends of the third sub-portion 2023 are respectively electrically connected to the second sub-portion 2022 and the signal input terminal 13.

In specific embodiments, an orthographic projection of the first opening on the base substrate covers an entire orthographic projection of the second sub-portion on the base substrate, the orthographic projection of the first opening on the base substrate is also overlapped with an orthographic projection of the first sub-portion on the base substrate, and the orthographic projection of the first opening on the base substrate is also overlapped with an orthographic projection of the third sub-portion on the base substrate.

In specific embodiments, a first-type signal line that does not include the second sub-portion but only the first sub-portion is provided.

In some embodiments, the second portion of a portion of the plurality of signal lines includes a first sub-portion extending along the first direction.

The first sub-portion is electrically connected to a corresponding the first additional conductive portion via the first opening.

In some embodiments, the second portion of a portion of the plurality of first-type signal lines includes a first sub-portion extending along the first direction Y. A line width of at least a portion of the first sub-portion is less than the line width of the first portion. The first sub-portion is electrically connected to a corresponding first additional conductive portion via the first opening. In specific embodiments, the first sub-portion of such a first-type signal line is electrically connected to the signal input terminal. For the first opening corresponding to such first-type signal line, an orthographic projection of the first opening on the base substrate at least is within an orthographic projection of a region, where the line width of the first sub-portion is less than the line width of the first portion, on the base substrate.

In specific embodiments, the plurality of signal lines also include second-type signal lines. In the second-type signal lines, a line width of any region of the second portion is not less than a line width of the first portion. A portion of the constant voltage signal lines and a portion of the common voltage signal lines are second-type signal lines. The constant voltage signal lines and the common voltage signal lines belonging to the second-type signal line also correspond to the first opening. That is, each constant voltage signal line and each common voltage signal line correspond to the first opening, such that each constant voltage signal line and each common voltage signal line are connected in parallel with the first additional conductive portion at the first openings, and thus the resistance is reduced and the heating issue of the constant voltage signal line and the common voltage signal line in the fan-out region is avoided. As shown in FIG. 4, using the constant voltage signal line VLED belonging to the second-type signal lines 2-2 as an example, the orthographic projection of the first opening 3011 on the base substrate is within an orthographic projection of the second portion 202 of the constant voltage signal line VLED belonging to the second-type signal lines 2-2 on the base substrate.

In specific embodiments, in a case where the signal line corresponds to both the first opening and the second opening, the first opening and the second opening are connected to form one opening.

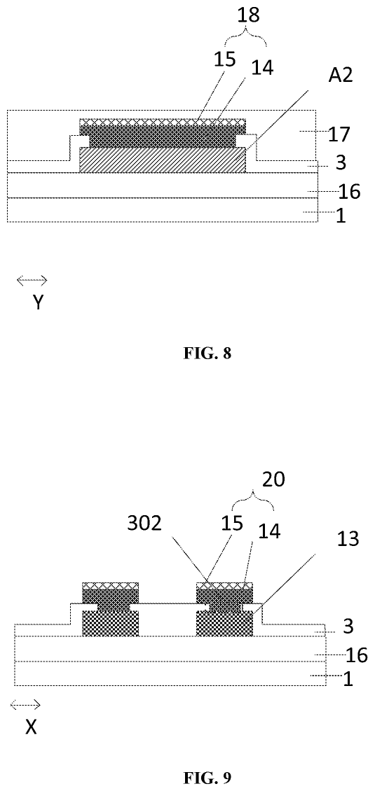

In some embodiments, as shown in FIG. 8, the wiring substrate further includes a first conductive portion 18 disposed on a side, facing away from the base substrate 1, of the pads (A2 in FIG. 8). The first conductive portion 18 and the additional conductive portion (not shown) are made of the same material.

It should be noted that FIG. 8 is a cross-sectional view along a line JJ′ in FIG. 3.

In some embodiments, the first conductive portion and the additional conductive portion are prepared by the same process.

In the wiring substrate according to some embodiments of the present disclosure, the additional conductive portion and the first conductive portion are made of the same material and prepared by the same process. That is, the additional conductive portion and the first conductive portion are disposed in the same layer, such that a pattern of the additional conductive portion is formed synchronously with the process of manufacturing the first conductive portion. In this way, without increasing the manufacturing process of the wiring substrate, the signal line is connected in parallel with the additional conductive portion and the resistance is reduced.

In some embodiments, as shown in FIG. 5 to FIG. 7, the additional conductive portion 4 includes a first sub-layer 14 and a second sub-layer 15 that are stacked on a side, facing away from the base substrate 1, of the signal lines 2.

In some embodiments, the signal line is made of copper, the first sub-layer included in the additional conductive section is made of nickel, and the second sub-layer included in the additional conductive section is made of gold.

In specific embodiments, the additional conductive portion is formed in an immersion gold process, where the first sub-layer, i.e., a nickel layer, is grown first, and the second sub-layer, i.e., a gold layer, is grown next.

In some embodiments, a thickness of the first sub-layer is greater than a thickness of the second sub-layer. The thickness of the first sub-layer is greater than a thickness of the opening.

In some embodiments, the thickness of the first sub-layer ranges from 4 microns to 5 microns, and the thickness of the second sub-layer ranges from 0.01 microns to 1 micron. That is, the thickness of nickel ranges from 4 microns to 5 microns, and the thickness of gold ranges from 0.01 microns to 1 micron.

In some embodiments, the thickness of the second sub-layer is about 0.035 microns.

In specific embodiments, because the first conductive portion and the additional conductive portion are disposed in the same layer, the first conductive portion also includes the first sub-layer and the second sub-layer that are stacked.

In specific implementations, in a case where the signal line and the pad are disposed in the same layer, the pad is made of copper. The first conductive portion and the additional conductive portion are prepared by the same process, thus, the first conductive portion is also formed in the immersion gold process, the first sub-layer included in the first conductive portion is made of nickel, and the second sub-layer included in the first conductive portion is made of gold. A thickness of the first sub-layer is greater than a thickness of the second sub-layer. That is, in the immersion gold process, the nickel layers of the first conductive portion and the additional conductive portion are grown first, and then the gold layers of the first conductive portion and the additional conductive portion are grown.

In some embodiments, the thickness of the additional conductive portion is the same as the thickness of the first conductive portion.

In some embodiments, the thickness of the first sub-layer of the additional conductive portion is the same as the thickness of the first sub-layer of the first conductive portion.

In some embodiments, the thickness of the second sub-layer of the additional conductive portion is the same as the thickness of the second sub-layer of the first conductive portion.

In some embodiments, as shown in FIG. 9, the wiring substrate further includes a second conductive portion 20 disposed on the side, facing away from the base substrate 1, of the signal input terminals 13. The second conductive portions 20 are in one-to-one correspondence to the signal input terminals 13.

The first protective layer further includes a plurality of exposed regions 302. An orthographic projection of the exposed region 302 on the base substrate 1 is within an orthographic projection of the signal input terminal 13 on the base substrate 1, and the second conductive portion 20 covers the signal input terminal 13 at the exposed region 302.

It should be noted that FIG. 9 is a cross-sectional view along a line HH′ of FIG. 4.

In some embodiments, the signal input terminal and the signal line are disposed in the same layer and electrically connected.

That is, in specific embodiments, for example, the signal input terminal, the signal line, and the pad are disposed in the same layer.

In some embodiments, the additional conductive portion and the second conductive portion are made of the same material.

In some embodiments, the additional conductive portion and the second conductive portion are prepared by the same process.

In the case where the additional conductive portion includes the first sub-layer and the second sub-layer that are stacked, accordingly, the second conductive portion includes a first sub-layer and a second sub-layer that are stacked.

In specific embodiments, in the case where the signal line and the signal input terminal are disposed in the same layer, the signal input terminal is also made of copper.

In specific embodiments, the first conductive portion and the additional conductive portion are prepared by the same process, thus, the second conductive portion is also formed in the immersion gold process, the first sub-layer included in the second conductive portion is made of nickel, and the second sub-layer included in the second conductive portion is made of gold. A thickness of the first sub-layer is greater than a thickness of the second sub-layer. That is, in the immersion gold process, the nickel layers of the second conductive portion and the additional conductive portion are grown first, and then the gold layers of the second conductive portion and the additional conductive portion are grown.

In some embodiments, the thickness of the additional conductive portion is the same as a thickness of the second conductive portion.

In some embodiments, the thickness of the first sub-layer of the additional conductive portion is the same as the thickness of the first sub-layer of the second conductive portion.

In some embodiments, the thickness of the second sub-layer of the additional conductive portion is the same as the thickness of the second sub-layer of the second conductive portion.

In specific embodiments, in a case where the wiring substrate includes both the additional conductive portion, the first conductive portion, and the second conductive portion, the additional conductive portion, the first conductive portion, and the second conductive portion are prepared by the same process. That is, the additional conductive portion, the first conductive portion, and the second conductive portion are disposed in the same layer.

In specific embodiments, the first conductive portion, the second conductive portion, and the additional conductive portion are disposed in the same layer, and each of the first conductive portion and the second conductive portion includes the first sub-layer and the second sub-layer. Therefore, the first conductive portion, the second conductive portion, and the additional conductive portion are formed in the immersion gold process. The nickel layers of the first conductive portion, the second conductive portion, and the additional conductive portion are first grown, and the gold layers of the first conductive portion, the second conductive portion, and the additional conductive portion are then grown. The thickness of the first conductive portion, the thickness of the second conductive portion, and the thickness of the additional conductive portion are the same. The thickness of the first sub-layer in the first conductive portion, the thickness of the first sub-layer in the second conductive portion, and the thickness of the first sub-layer in the additional conductive portion are the same. The thickness of the second sub-layer in the first conductive portion, the thickness of the second sub-layer in the second conductive portion, and the thickness of the second sub-layer in the additional conductive portion are the same. The thickness of the first sub-layer is greater than the thickness of the second sub-layer. The thickness of the first sub-layer is greater than the thickness of the opening.

It should be noted that the second conductive portion is used to protect the signal input terminal and is also bound to the drive control module.

In the wiring substrate according to some embodiments of the present disclosure, the additional conductive portion and the second conductive portion are disposed in the same layer, such that the pattern of the additional conductive portion is formed synchronously with the process of manufacturing the second conductive portion. In this way, without increasing the manufacturing process of the wiring substrate, the signal line is connected in parallel with the additional conductive portion, and the resistance is reduced.

In some embodiments, the second conductive portion covers the signal input terminal in the exposed region.

In some embodiments, as shown in FIG. 5 to FIG. 7, in the second direction X, a first spacing h1 is defined between an edge of the opening 301 and an edge of the signal line 2 adjacent to the opening.

That is, in a case where the orthographic projection of the opening on the base substrate is within the orthographic projection of the signal line on the base substrate, in the second direction, the width of the opening is less than the line width of the signal line at the opening, and the first protective layer enclosing the opening needs to cover the edge of the signal line. Therefore, the short circuit caused by errors in the etching process that result in openings exposing adjacent signal lines is avoided.

In some embodiments, the first spacing is greater than or equal to 5 micrometers.

It should be noted that when manufacturing the signal line and the first protective layer, a shielding width of the first protective layer and the signal line is about 5 micrometers due to the process. Considering the dimensional deviation brought about by the manufacturing, the first spacing is defined to be greater than 8 micrometers.

In specific embodiments, for example, the first spacing is defined to be less than or equal to 100 micrometers.

In some embodiments, as shown in FIG. 5 and FIG. 6, in a direction perpendicular to the base substrate 1, the thickness of the first additional conductive portion 401 is greater than a depth of the first opening 3011. As shown in FIG. 7, the thickness of the second additional conductive portion 402 is greater than a depth of the second opening 3012.

In some embodiments, the orthographic projection of the additional conductive portion on the base substrate is within the orthographic projection of its corresponding signal line on the base substrate.

It should be noted that in a case where the additional conductive portion is formed using the immersion gold process, because the immersion gold process uses the substitution principle to successively grow the nickel layer and the gold layer on the metal layer, the line width of the additional conductive layer formed by the immersion gold process is limited by the line width of the signal line corresponding thereto. In specific embodiments, in a direction perpendicular to an extension direction of the additional conductive portion and the signal line corresponding thereto, the line width of the additional conductive portion is less than or equal to the line width of the signal line corresponding thereto.

In some embodiments, as shown in FIG. 5 to FIG. 7, the orthographic projection of the additional conductive portion 4 on the base substrate 1 covers an orthographic projection of an edge of the first protective layer 3 at the opening 301 on the base substrate 1.

In some embodiments, as shown in FIG. 5 to FIG. 7, in the direction perpendicular to the extension direction of the additional conductive portion and the signal line corresponding thereto, the line width of the additional conductive portion 4 is equal to the line width of the signal line 2 corresponding thereto.

In specific embodiments, in the case where the additional conductive portion is formed by the immersion gold process, in the direction perpendicular to the extension direction of the additional conductive portion and the signal line corresponding thereto, the line width of the additional conductive portion is equal to the line width of the signal line corresponding thereto, such that the line width of the additional conductive portion is maximized in case of process limitations, and thus the resistance of the signal line connected in parallel with the additional conductive portion is minimized, and the impedance is minimized, which is more conducive to achieving the narrow bezel and avoiding the heating issue in the fan-out region.

It should be noted that in FIG. 5 and FIG. 6, the additional conductive portion 4 and the signal line 2 corresponding thereto extend along the first direction, and thus in the second direction X, the line width of the additional conductive portion 4 is equal to the line width of the signal line 2 corresponding thereto. In FIG. 7, the additional conductive portion 4 and the signal line 2 corresponding thereto extend along the second direction, and thus in the first direction Y, the line width of the additional conductive portion 4 is equal to the line width of the signal line 2 corresponding thereto.

In some embodiments, as shown in FIG. 5, FIG. 6, and FIG. 7, the wiring substrate further includes a second protective layer 17, disposed on the side, facing away from the signal lines 2, of the additional conductive portion 4 and covering the additional conductive portion 4.

In some embodiments, the orthographic projection of the first opening on the base substrate is within an orthographic projection of the second protective layer on the base substrate, and the orthographic projection of the second opening on the base substrate is within the orthographic projection of the second protective layer on the base substrate.

In some embodiments, the first protective layer is made of at least one of silicon nitride, silicon oxide, silicon nitride, and amorphous silicon.

In some embodiments, the second protective layer is made of white ink.

The wiring substrate according to some embodiments of the present disclosure utilizes white ink to protect the additional conductive portion, which effectively prevents corrosion-type defects from occurring to the additional conductive portion.

In specific embodiments, the second protective layer is coated on an entire surface but needs to expose the first conductive portion and the second conductive portion. For example, the orthographic projection of the second protective layer on the base substrate is not overlapped with the orthographic projection of the first conductive portion on the base substrate, and the orthographic projection of the second protective layer on the base substrate is not overlapped with the orthographic projection of second conductive portion on the base substrate. That is, the second protective layer includes a first open region exposing the first conductive portion and a second open region exposing the second conductive portion.

In specific embodiments, the first conductive portion and the second conductive portion are blocked by a mesh plate, and then the second protective layer is coated on the entire surface, such that locations blocked by the mesh plate are not coated with the second protective layer. That is, regions covered by the mesh panel correspond to the first opening region and the second opening region.

In specific embodiments, the second conductive portion corresponds to the signal input terminal, a distance between adjacent second conductive portions is small. Therefore, regions where the plurality of second conductive portions are disposed in the fan-out region are not coated with the second protective layer. That is, the orthographic projection of the plurality of second conductive portions on the base substrate is within the orthographic projection of the second opening region on the base substrate.

In some embodiments, as shown in FIG. 4, a distance h4 between the first opening 3011 and the exposed region 302 is greater than 0 in the first direction Y.

In the wiring substrate according to some embodiments of the present disclosure, in a case where the second protective layer is white ink and an orthographic projection of the white ink completely covers the orthographic projection of the first opening on the base substrate, the distance between the first opening and the exposed region is greater than 0 in the first direction due to the limitation of the coating precision of white ink, such that the white ink does not cover the second conductive portion.

In some embodiments, the minimum distance between the first opening and the signal input terminal in the first direction ranges from 0.3 micrometers to 1 micrometer. This distance is the distance h4 between the first opening and the exposed region in the first direction.

It should be noted that in the case where the orthographic projection of the white ink completely covers the orthographic projection of the first opening on the base substrate, and the white ink does not cover the second conductive portion, the smaller h4 is the better. For example, the distance h4 is greater than the coating precision of white ink. The coating precision of different kinds of white ink is different, and thus different kinds of white ink correspond to different distances h4. In a case where the white ink is thermosetting white ink, the distance h4 between the first opening and the exposed region is greater than 1 millimeter. In a case where the white ink is a photographic white ink, the distance h4 between the first opening and the exposed region is greater than 0.3 millimeters.

In some embodiments, the signal line includes only one layer of conductive layer. That is, the signal line is a single-layer wiring. The signal input terminal also includes only one layer of conductive layer, and the pad includes only one layer of conductive layer.

In specific embodiments, to reduce the process steps and save production costs, the various types of pads, constant voltage signal lines, cascade lines, address signal lines, feedback signal lines, power signal lines, first connecting leads, common voltage signal lines, and signal input terminals are disposed in the same layer. That is, the above structures are disposed in the same conductive layer. It should be noted that, in the present disclosure, the term “disposed in the same layer” refers to a layer structure, wherein film layers for producing specific patterns are formed by using the same film-forming process, and then the layer structure is formed by performing a one-time patterning process using the same mask plate. That is, the one-time patterning process corresponds to one mask plate. Depending on the specific pattern, the one-time patterning process includes an exposure, development, or etching process, the specific patterns in the formed layer structure are continuous or discontinuous, and these specific patterns are at the same height or have the same thickness, or at different heights or have different thicknesses.

In specific embodiments, the first insulation layer also has a plurality of via holes. The plurality of via holes expose regions of the first sub-pad, the second sub-pad, and each pad included in the second pad group, and the first conductive portion covers the pads in the regions where the pads are exposed by the via holes, such that the light-emitting element is electrically connected to the first pad group by the first conductive portion at the via hole, and the drive chip is electrically connected to the second pad group by the first conductive portion at the via hole. It should be noted that in FIG. 2 and FIG. 3, regions, outlined by the dashed lines, at the first sub-pad A-1, the second sub-pad A-2, and the ground pad 5021, the output pad 5023, the address pad 5024, and the power pad 5022 included in the second pad group 502 are locations where the corresponding via holes are located.

It should be noted that, as shown in FIG. 5 to FIG. 9, the wiring substrate also includes a buffer layer 16. The buffer layer 16 is disposed between the base substrate 1 and a film layer where the signal line 2 and the signal input terminal 13 are dispose, such that the conductive layer, such as the first pad, is prevented from being directly disposed on the base substrate, which is otherwise prone to fall off.

The description of the present disclosure embodiments of reducing the resistance and lowering the impedance is given hereinafter using a scenario where the signal line is made of copper, the first sub-layer is made of nickel, and the second sub-layer is made of gold as an example. A resistivity of copper is 1.75×10−8 ohm·cm, a resistivity of nickel is 6.84×10−8 ohm·cm, and a resistivity of gold is 2.4×10−8 ohm·cm. A thickness of copper is 1.8 microns and the impedance is R. In a case where the thickness of the additional conductive portion ranges from 4 microns to 5 microns, the impedance is 1.4 R to 1.8 R. The impedance of copper that is connected in parallel with the nickel and gold additional conductive portions ranges from 0.58 R to 0.64 R, which is reduced by 36% to 42% compared to the impedance R in the case of arranging the copper signal line only. In some practices, in the case where only the copper signal line is arranged, the line width of the common voltage signal line in the first bezel region and the line width of the constant voltage signal line in the second bezel region are 1 mm. With the impedance unchanged, in a case where the copper is connected in parallel with the nickel and gold additional conductive layer, the line width is reduced by 0.36 mm to 42 mm. Correspondingly, the widths of the first bezel region and the second bezel region in the second direction are reduced by 0.36 mm to 42 mm.

Some embodiments of the present disclosure provide a light-emitting substrate. The light-emitting substrate includes a wiring substrate according to some embodiments of the present disclosure, and a plurality of light-emitting elements disposed on a side of the wiring substrate.

In some embodiments, the wiring substrate includes pads, and the light-emitting elements are electrically connected to the wiring substrate by the pads.

In some embodiments, a first conductive portion is disposed between the pad and the light-emitting element.

In some embodiments, the light-emitting substrate further includes a plurality of drive chips.

In some embodiments, in a case where the wiring substrate includes a plurality of first pad groups and a plurality of second pad groups, the light-emitting element is electrically connected to the first pad group, and the drive chip is electrically connected to the second pad group.

In specific embodiments, the light-emitting element has two pins, and the two pins are electrically connected to a first sub-pad and a second sub-pad of the first pad, respectively. The drive chip has four pins, and the four pins are electrically connected to a ground pad, an output pad, an address pad, and a power pad, respectively.

In some embodiments, the light-emitting element is a micro-sized inorganic light-emitting diode.

In specific embodiments, the micro-sized inorganic light-emitting diode is, for example, a mini light-emitting diode (Mini-LED) or a micro light-emitting diode (Micro-LED). The Mini-LED and Micro-LED have small size and high brightness, which are widely used in display devices or their backlight modules. For example, a typical size (e.g., a length) of the Micro-LED is less than 100 microns, e.g., 10 microns to 80 microns, and a typical size (e.g., a length) of the Mini-LED ranges from 80 microns to 350 microns, e.g., 80 microns to 120 microns. The light-emitting element is at least one of the Micro-LED or the Mini-LED.

In specific embodiments, the light-emitting substrate is applied in the display field, for example, the light-emitting substrate serves as a backlight source for a display panel.

The light-emitting substrate according to some embodiments of the present disclosure includes the wiring substrate according to some embodiments of the present disclosure. For the implementation of the light-emitting substrate, reference is made to the embodiments of the wiring panel described above, which is not repeated herein.

In summary, in the wiring substrate according to some present embodiments of the present disclosure, i.e., the light-emitting substrate, the first protective layer includes the opening that exposes the signal line, and the region of the signal line exposed by the opening is electrically connected to the additional conductive portion by being in contact with the additional conductive portion, which is equivalent to the additional conductive portion being connected in parallel with the signal line, such that the additional conductive portion and the signal line together sever as wiring for transmitting signals. Comparted to the case where only the signal line is provided, the resistance of the wiring for transmitting signals is reduced. In the case where the first protective layer includes the first opening, at least a portion of the signal lines disposed in the fan-out region is electrically connected to the first additional conductive portion at the first opening, such that the resistance of the signal line in the fan-out region is reduced. Even if the line width of the signal line becomes smaller after the signal line extends into the fan-out region, the heating of the signal line in the fan-out region is avoided. In the case where the first protective layer includes the second opening, at least a portion of the signal lines disposed in the first region is covered by the second conductive portion at the second opening, such that the resistance of the signal line in the first region is reduced, and thus the line width of the signal line in the first region is reduced when satisfying the need for the impedance of the signal line, which facilitates the achievement of the narrow bezel.

Although embodiments of the present invention have been described, those skilled in the art may make additional changes and modifications to these embodiments once the basic inventive concepts are known. Therefore, the appended claims are intended to be construed to include the embodiments as well as all changes and modifications that fall within the scope of the present invention.

Obviously, those skilled in the art may make various changes and variations to the embodiments of the present invention without departing from the spirit and scope of the embodiments of the present invention. Thus, if these modifications and variations of the embodiments of the present invention fall within the scope of the claims of the present invention and their technical equivalents, the present invention is intended to encompass all these modifications and variations as well.

1. A wiring substrate, comprising:
a base substrate, comprising a first region and a fan-out region disposed on a side of the first region in a first direction;
a plurality of signal lines disposed on a side of the base substrate, wherein the plurality of signal lines are arranged along a second direction and extend from the first region to the fan-out region, the first direction being intersected with the second direction, and each of the plurality of signal lines comprises a first portion disposed in the first region and a second portion disposed in the fan-out region;
a first protective layer disposed on a side, facing away from the base substrate, of the signal lines, wherein the first protective layer comprises a plurality of openings, an orthographic projection of the openings on the base substrate being overlapped with an orthographic projection of the signal lines on the base substrate; and
a plurality of additional conductive portions disposed on the side, facing away from the base substrate, of the signal lines, wherein an orthographic projection of the additional conductive portions on the base substrate is overlapped with the orthographic projection of the openings on the base substrate, and the orthographic projection of the additional conductive portions on the base substrate is overlapped with the orthographic projection of the signal lines on the base substrate; wherein
the plurality of openings comprise at least one of a first opening and a second opening, the first opening being disposed in the fan-out region and the second opening being disposed in the first region; and
the plurality of additional conductive portions comprise at least one of a first additional conductive portion and a second additional conductive portion, the first additional conductive portion being electrically connected to the signal line at the first opening and the second additional conductive portion being electrically connected to the signal line at the second opening.

2. The wiring substrate according to claim 1, wherein the plurality of signal lines comprise common voltage signal lines and constant voltage signal lines; wherein
at least a portion of the common voltage signal lines corresponds to at least one of the first opening and the second opening; and
at least a portion of the constant voltage signal lines corresponds to at least one of the first opening and the second opening.

3. The wiring substrate according to claim 2, wherein
the first region comprises a pad region, and a first bezel region and a second bezel region that are disposed in the second direction on each side of the pad region; and
the wiring substrate comprises a plurality of the common voltage signal lines and a plurality of the constant voltage signal lines; wherein
the first bezel region comprises one of the plurality of the common voltage signal lines, and the rest of the plurality of the common voltage signal lines run through the pad region;
the second bezel region comprises one of the plurality of the constant voltage signal lines, and the rest of the plurality of the constant voltage signal lines run through the pad region;
the common voltage signal line in the first bezel region corresponds to at least one of the second openings;
the second additional conductive portion is electrically connected to the corresponding common voltage signal line in the first bezel region via the second opening; and
a line width of the common voltage signal line in the first bezel region is less than a line width of the common voltage signal line in at least a portion of the pad region.

4. The wiring substrate according to claim 2, wherein
the first region comprises a pad region, and a first bezel region and a second bezel region that are disposed in the second direction on each side of the pad region; and
the wiring substrate comprises a plurality of the common voltage signal lines and a plurality of the constant voltage signal lines; wherein
the first bezel region comprises one of the plurality of the common voltage signal lines, and the rest of the plurality of the common voltage signal lines run through the pad region;
the second bezel region comprises one of the plurality of the constant voltage signal lines, and the rest of the plurality of the constant voltage signal lines run through the pad region;
the constant voltage signal line in the second bezel region corresponds to at least one of the second openings;
the second additional conductive portion is electrically connected to the corresponding constant voltage signal line in the second bezel region via the second opening; and
a line width of the constant voltage signal line in the second bezel region is less than a line width of the constant voltage signal line in at least a portion of the pad region.

5. The wiring substrate according to claim 3, wherein at least a portion of the plurality of the common voltage signal lines and/or the plurality of the constant voltage signal lines belong to first-type signal lines; wherein
in each of the first-type signal lines, a line width of at least a partial region of the second portion is less than a line width of the first portion; and
at least a portion of the first-type signal lines is electrically connected to the corresponding first additional conductive portion via the first opening.

6. The wiring substrate according to claim 5, wherein the second portion of at least a portion of a plurality of the first-type signal lines comprises: a first sub-portion extending along the first direction and electrically connected to the first portion, and a second sub-portion extending along the second direction and electrically connected to the first sub-portion;
wherein on a same one of the first-type signal lines, a line width of at least a partial region of the second sub-portion is less than the line width of the first portion, and the second sub-portion is electrically connected to the corresponding first additional conductive portion via the first opening.

7. The wiring substrate according to claim 1, wherein the second portion of a portion of the plurality of signal lines comprises a first sub-portion extending along the first direction;
wherein the first sub-portion is electrically connected to the corresponding first additional conductive portion via the first opening.

8. The wiring substrate according to claim 1, wherein the orthographic projection of the opening on the base substrate is within the orthographic projection of the signal line on the base substrate, and in the second direction, a first spacing is defined between an edge of the opening and an edge of the signal line adjacent to the opening.

9. (canceled)

10. The wiring substrate according to claim 1, wherein in a direction perpendicular to the base substrate, a thickness of the first additional conductive portion is greater than a depth of the first opening, and a thickness of the second additional conductive portion is greater than a depth of the second opening.

11. The wiring substrate according to claim 10, wherein the orthographic projection of the opening on the base substrate is within the orthographic projection of the additional conductive portion on the base substrate, and the orthographic projection of the additional conductive portion on the base substrate covers an orthographic projection of an edge of the first protective layer at the opening on the base substrate.

12. The wiring substrate according to claim 10, wherein the orthographic projection of the additional conductive portion on the base substrate is within the orthographic projection of the signal line corresponding to the additional conductive portion on the base substrate.

13. The wiring substrate according to claim 1, wherein the additional conductive portion comprises a first sub-layer and a second sub-layer that are successively stacked on the side, facing away from the base substrate, of the signal lines.

14-15. (canceled)

16. The wiring substrate according to claim 1, further comprising: a plurality of pads disposed in the first region and a first conductive portion disposed on a side, facing away from the base substrate, of the pads;
wherein the first conductive portion and the additional conductive portion are made of a same material.

17-18. (canceled)

19. The wiring substrate according to claim 1, further comprising: a second protective layer, disposed on a side, facing away from the signal lines, of the additional conductive portion and covering the additional conductive portion.

20. The wiring substrate according to claim 19, wherein an orthographic projection of the first opening on the base substrate is within an orthographic projection of the second protective layer on the base substrate, and an orthographic projection of the second opening on the base substrate is within the orthographic projection of the second protective layer on the base substrate.

21. The wiring substrate according to claim 19, wherein the first protective layer is made of at least one of silicon nitride, silicon oxide, silicon nitride oxide, or amorphous silicon, and the second protective layer is made of white ink.

22. The wiring substrate according to claim 1, further comprising: a plurality of signal input terminals; wherein
the plurality of signal input terminals disposed in the fan-out region on a same side of the base substrate as the signal lines, the plurality of signal input terminals are arranged along the second direction, and the plurality of signal input terminals are electrically connected to the signal lines; and
a portion of the first protective layer is disposed between the first opening and the signal input terminal.

23. (canceled)

24. The wiring substrate according to claim 22, further comprising: a second conductive portion disposed on a side, facing away from the base substrate, of the signal input terminals, wherein the second conductive portions are in one-to-one correspondence to the signal input terminals; wherein
the first protective layer comprises a plurality of exposed regions, wherein an orthographic projection of the exposed regions on the base substrate is within an orthographic projection of the signal input terminals on the base substrate, and the second conductive portion covers the signal input terminal in the exposed region; and
the second conductive portion and the additional conductive portion are made of a same material.

25. (canceled)

26. The wiring substrate according to claim 3, wherein the plurality of pads are organized into a plurality of pad groups; wherein
the plurality of pad groups are disposed in the pad region on a same side of the base substrate as the signal lines, and the plurality of pad groups comprise a plurality of pad group columns arranged along the second direction and extending along the first direction;
each of the plurality of pad group columns corresponds to one of the constant voltage signal lines and one of the common voltage signal lines, and one of the constant voltage signal lines and one of the common voltage signal lines corresponding to each of the plurality of pad group columns are respectively disposed on two sides of the pad group column in the second direction;
each of the plurality of pad groups comprises a first pad group and a second pad group;
the first pad group comprises a plurality of first pads, and the constant voltage signal line is electrically connected to one of the plurality of first pads; and
the second pad group comprises a ground pad, an output pad, an address pad, and a power pad; wherein the output pad and the ground pad are arranged as a first row of pad rows along the second direction, the address pad and the power pad are arranged as a second row of pad rows along the second direction, and the ground pad is electrically connected to the common voltage signal line.

27. A light-emitting substrate, comprising: a wiring substrate and a plurality of light-emitting elements disposed on a side of the wiring substrate; wherein
the wiring substrate comprises:
a base substrate, comprising a first region and a fan-out region disposed on a side of the first region in a first direction;
a plurality of signal lines disposed on a side of the base substrate, wherein the plurality of signal lines are arranged along a second direction and extend from the first region to the fan-out region, the first direction being intersected with the second direction, and each of the plurality of signal lines comprises a first portion disposed in the first region and a second portion disposed in the fan-out region;
a first protective layer disposed on a side, facing away from the base substrate, of the signal lines, wherein the first protective layer comprises a plurality of openings, an orthographic projection of the openings on the base substrate being overlapped with an orthographic projection of the signal lines on the base substrate; and
a plurality of additional conductive portions disposed on the side, facing away from the base substrate, of the signal lines, wherein an orthographic projection of the additional conductive portions on the base substrate is overlapped with the orthographic projection of the openings on the base substrate, and the orthographic projection of the additional conductive portions on the base substrate is overlapped with the orthographic projection of the signal lines on the base substrate; wherein
the plurality of openings comprise at least one of a first opening and a second opening, the first opening being disposed in the fan-out region and the second opening being disposed in the first region; and
the plurality of additional conductive portions comprise at least one of a first additional conductive portion and a second additional conductive portion, the first additional conductive portion being electrically connected to the signal line at the first opening and the second additional conductive portion being electrically connected to the signal line at the second opening; and
the light-emitting elements are electrically connected to the wiring substrate by pads.

28-29. (canceled)
